(19) United States
(12) Patent Application Publication
(10) Pub. No.: US 2008/0272784 A1
(43) Pub. Date: Nov. 6, 2008

(54) Magnetic Resonance Imaging Device and Method for Operating a Magnetic Resonance Imaging Device

(75) Inventors: Paul Royston Harvey, Eindhoven (NL); Gerardus Nerius Peeren, Eindhoven (NL)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N.V., Eindhoven (NL)

(21) Appl. No.: 11/571,002

(22) PCT Filed: Jun. 24, 2005
(86) PCT No.: PCT/IB2005/052097

§ 371 Date: Dec. 20, 2006

(30) Foreign Application Priority Data
Jun. 29, 2004 (EP) 04103023.0

(51) Int. Cl. G01R 33/385

(52) U.S. Cl. 324/318

(57) ABSTRACT

The present invention relates to a magnetic resonance imaging (MRI) device and to a method for operating it. The basic components of an MRI device are the main magnet system (2) for generating a steady magnetic field, the gradient system (3) with at least one gradient coil, the RF system and the signal processing system. According to the present invention, the gradient coil is split into sub-coils (S1, S2) at least in the direction of the steady magnetic field. By doing so, the amplitude of the non-imaging component of the gradient field in the vicinity of the patient is reduced, leading to reduced peripheral nerve stimulation and thus enhanced image quality.

The present invention relates to a magnetic resonance imaging device, comprising at least a main magnet system for generating a steady magnetic field in a measuring space of the magnetic resonance imaging device, a gradient system with at least one gradient coil for generating a magnetic gradient field in said measuring space, wherein the magnetic gradient field has at least one component that is perpendicular to the steady magnetic field.

The invention further relates to a method for operating such a magnetic resonance imaging device.

The basic components of a magnetic resonance imaging (MRI) device are the main magnet system, the gradient system, the RF system and the signal acquisition and processing system. The main magnet system of a modern superconducting cylindrical MRI system is typically contained within a cryostat. For cylindrical MRI systems, the main magnet system comprises a cylindrical bore defining a measuring space and enabling the entry of an object to be analyzed by the MRI device. For open type MRI systems, the magnet consists of two pole pieces. The main magnet system generates a strong uniform static field for polarization of nuclear spins in the object to be analyzed. The gradient system is designed to produce time-varying magnetic fields of controlled spatial non-uniformity. The gradient system is a crucial part of the MRI device, because gradient fields are essential for signal localization. The RF system mainly consists of a transmitter coil and a receiver coil, wherein the transmitter coil is capable of generating a magnetic field for excitation of a spin system, and wherein the receiver coil converts a processing magnetization into electrical signals. The signal processing system generates images on the basis of the electrical signals.

The switching of gradient fields can trigger peripheral nerve stimulation (PNS) in a living object to be examined, e.g. a human or an animal body during magnetic resonance image exposures. The gradient fields acting on the object are characterized by a magnetic flux density that changes over time and that produces electric fields within the object to be examined. PNS depends among others on the gradient change with time and occurs mainly at the highest rates of gradient change with time.

US 2001/0031918 A1 teaches a method for operating a magnetic resonance tomography apparatus, in order to suppress PNS. The method comprises the steps of generating a basic magnetic field, generating a gradient magnetic field having a main field component that is co-linear with the basic magnetic field and a predetermined main gradient, and at least one accompanying field component perpendicular to the main field component, and having a linearity volume, and the step of activating an additional magnetic field that is as homogeneous as possible and extends beyond the linearity volume, and that is switched at least for a time period in which the gradient field is also switched, and that is oriented such that it reduces at least one of the field components in at least one region in which PNS is anticipated, in order to avoid it. The method is further explained with respect to reducing the main field component of the gradient field. The respective magnetic resonance tomography apparatus comprises an additional coil arrangement for producing the additional magnetic field, or the gradient coil system has a gradient coil for producing the gradient field, wherein the gradient coil is fashioned such that the additional magnetic field and the gradient field can be produced, or the apparatus for producing the additional magnetic field has an arrangement for modifying the basic magnetic field. US 2001/0031918 A1 does not disclose how to realize a gradient coil such that the additional magnetic field and the gradient field can be produced in order to actually suppress PNS, except, that the gradient coil has two partial coils that can be driven independently from each other.

It is an object of the invention to provide a magnetic resonance imaging device of the kind mentioned in the opening paragraphs that enables magnetic resonance image exposures with minimized peripheral nerve stimulation (PNS) in the object to be examined while still delivering the required imaging gradient fields at iso-center where the image of the object to be examined, e.g. a human or animal body is taken.

In order to achieve this object, a magnetic resonance imaging device in accordance with the invention is characterized in that the gradient coil is split into sub-coils at least in the direction of the steady magnetic field such that the magnetic gradient field component perpendicular to the steady magnetic field is reduced in a least one region of the measuring space. Thanks to this measures, PNS in a living object to be examined is suppressed.

Preferably, the sub-coils are driven by separate amplifiers. In addition, they can be connected in a series or in a parallel configuration. In preferred embodiments, the sub-coils are arranged to permit for switching between parallel and series configuration.

Preferably, at least one sub-coil operates with a current offset in addition to the time dependent current needed for generating the magnetic gradient field. In preferred embodiments the gradient coil is divided into two sub-coils and one sub-coil operates with the inverse current offset of the other sub-coil. The polarity of the current offset depends on the winding direction.

Preferably, each sub-coil is driven by a separate amplifier, the sub-coils are electrically connected in a parallel or series configuration and at least one sub-coil operates with a current offset in addition to the time dependent current needed for generating the magnetic gradient field.

Preferably, the magnetic resonance imaging device comprises a processing unit to calculate, before an exposure, the best sub-coil configuration and/or the best current offset for a required image quality while minimizing the peripheral nerve stimulation to be expected in the object to be examined.

Preferably, each sub-coil is shielded independently.

A method for operating a magnetic resonance imaging device in accordance with the invention comprises the steps of calculating the best sub-coil configuration and/or best current offset for the required image quality while minimizing the peripheral nerve stimulation to be expected in the object to be examined before making an exposure and generating the magnetic gradient field with a reduced magnetic field component perpendicular to the steady magnetic field by using the calculated best sub-coil configuration and/or the calculated best current offset, a computer program product with corresponding instructions and a data carrier on which the program is stored.

Embodiments of a magnetic resonance imaging (MRI) device in accordance with the invention and of a method for operating a magnetic resonance imaging device in accordance with the invention will be explained in the following with reference to the drawings, in which

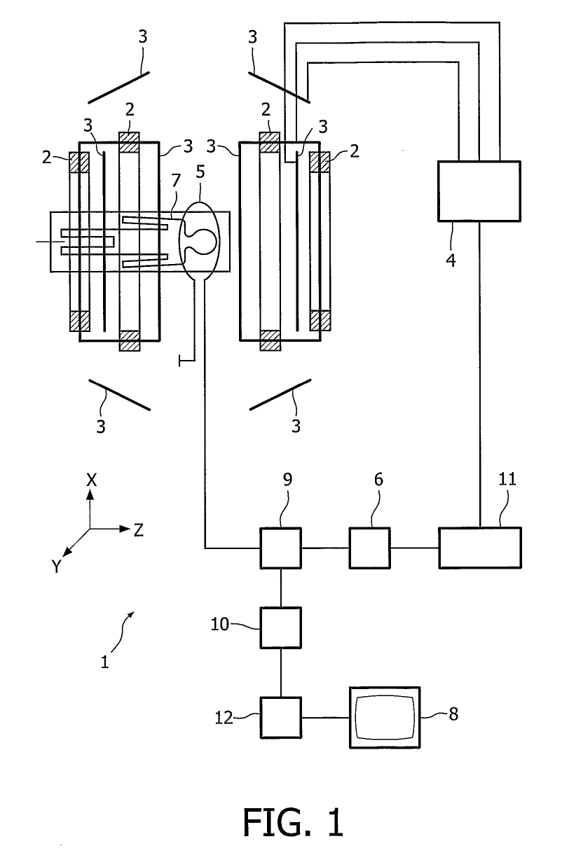

FIG. 1 shows an MRI device according to the prior art;

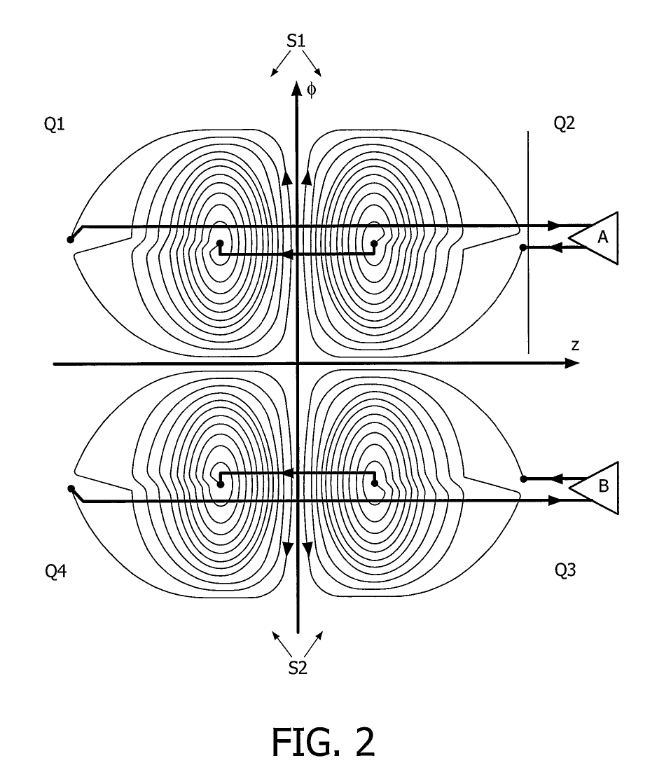

FIG. 2 shows a gradient system of an MRI device according to the prior art;

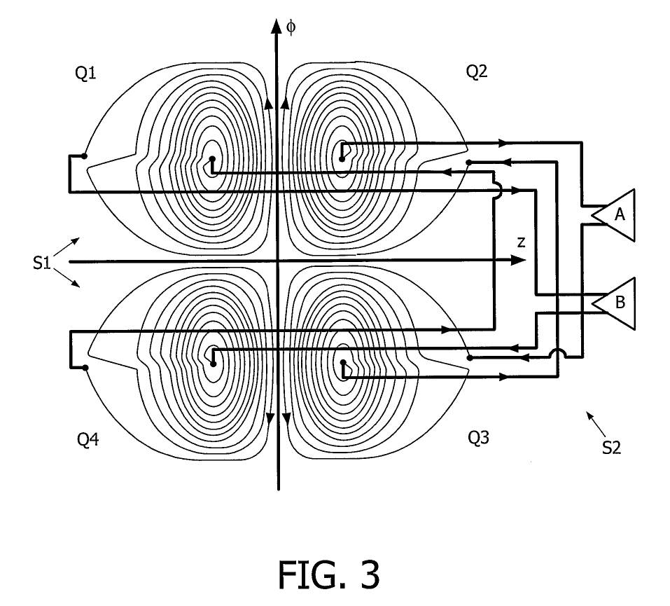

FIG. 3 shows a first embodiment of a gradient system for an MRI device according to the invention;

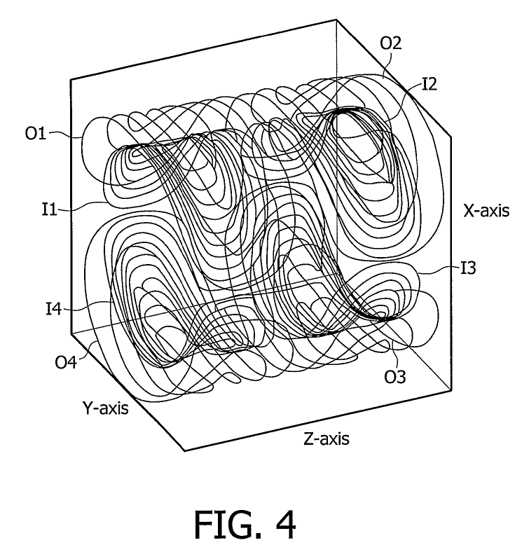

FIG. 4 shows a single axis shielded gradient coil;

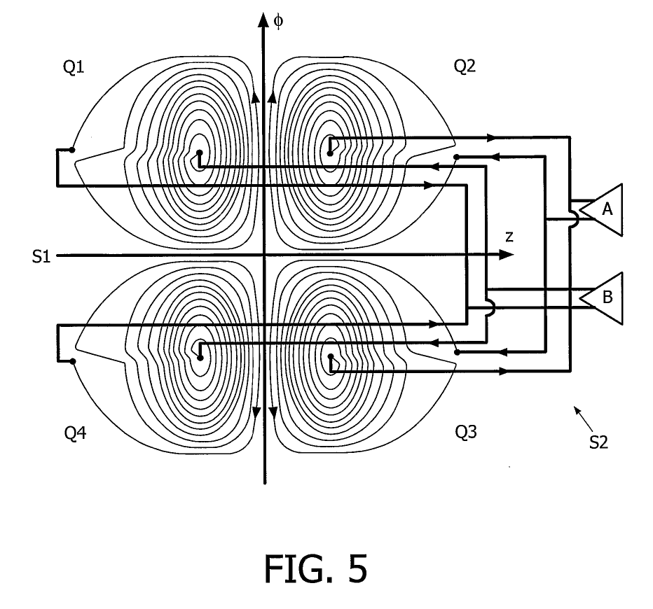

FIG. 5 shows a second embodiment of a gradient system for an MRI device according to the invention;

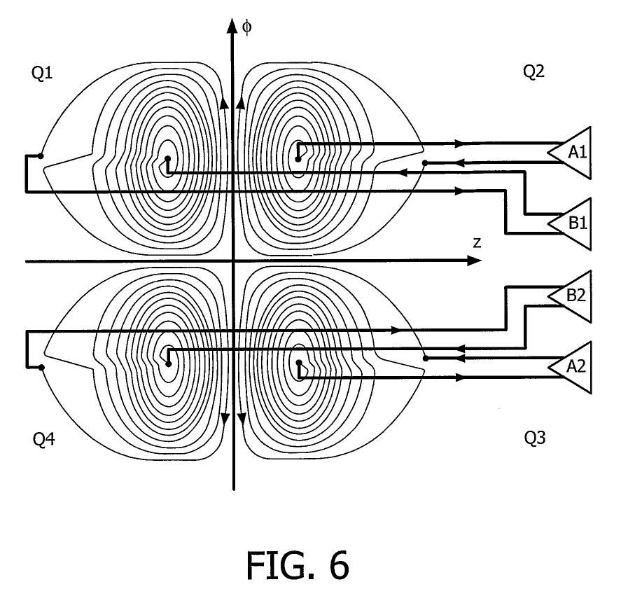

FIG. 6 shows a third embodiment of a gradient system for a MRI device according to the invention;

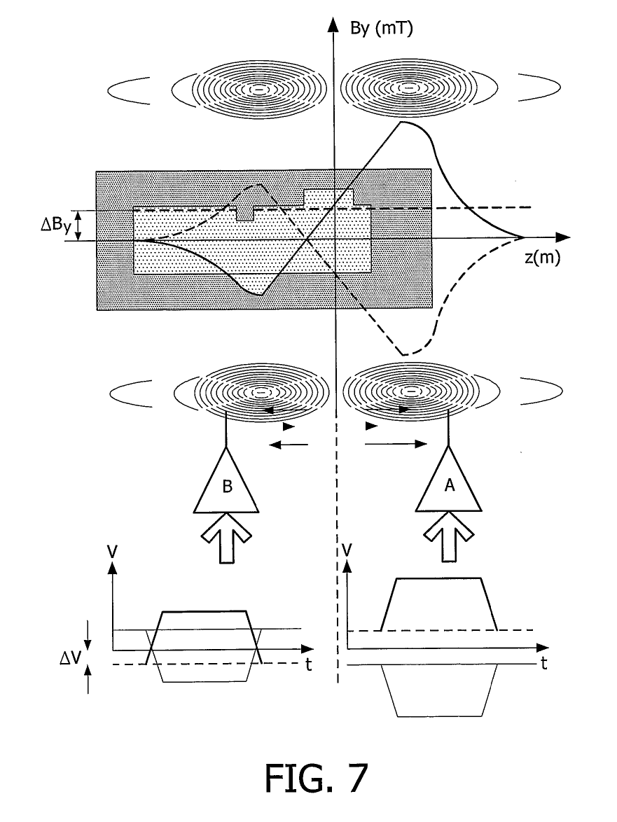

FIG. 7 schematically shows the relative voltage demand on each amplifier per gradient coil half and the resulting magnetic field component.

FIG. 1 shows a cylindrical magnetic resonance imaging (MRI) device 1 known from prior art which includes a main magnet system 2 for generating a steady magnetic field, and also several gradient coils providing a gradient system 3 for generating additional magnetic fields having a gradient in the X, Y, Z directions. The Z direction of the coordinate system shown corresponds to the direction of the steady magnetic field in the main magnet system 2 by convention. The Z axis is an axis co-axial with the axis of a bore hole of the main magnet system 2, wherein the X axis is the vertical axis extending from the center of the magnetic field, and wherein the Y axis is the corresponding horizontal axis orthogonal to the Z axis and the X axis.

The gradient coils of the gradient system 3 are fed by a power supply unit 4. An RF transmitter coil 5 serves to generate RF magnetic fields and is connected to an RF transmitter and modulator 6. A receiver coil is used to receive the magnetic resonance signal generated by the RF field in the object 7 to be examined, for example a human or animal body. This coil may be the same coil as the RF transmitter coil 5. Furthermore, the main magnet system 2 encloses an examination space, which is large enough to accommodate a part of the body 7 to be examined. The RF coil 5 is arranged around or on the part of the body 7 to be examined in this examination space. The RF transmitter coil 5 is connected to a signal amplifier and demodulation unit 10 via a transmission/reception circuit 9.

The control unit 11 controls the RF transmitter and modulator 6 and the power supply unit 4 so as to generate special pulse sequences, which contain RF pulses and gradients. The phase and amplitude obtained from the demodulation unit 10 are applied to a processing unit 12. The processing unit 12 processes the presented signal values so as to form an image by transformation. This image can be visualized, for example by means of a monitor 8.

The present invention provides a gradient system and an MRI device containing such a gradient system that allow for minimized or no PNS at all in a living object, e.g. an animal or a human body during exposure by using a gradient system with one or more gradient coils split into sub-coils at least in the direction of the steady magnetic field such that the gradient field component perpendicular to the steady magnetic field is reduced in at least one region of the measuring space. Especially in the case of a cylindrical topology where the perpendicular component would normally be large, the gradient field component perpendicular to the steady magnetic field of the main magnet system is reduced for preventing PNS. By doing so, the amplitude of the non-imaging component of the gradient field in the vicinity of the patient is reduced, leading to reduced PNS. In the coordinates as shown in FIG. 1, especially the y-component of the gradient field would be reduced to avoid artifacts in the images. The x-component might be reduced, too, for the sake of the patient's comfort. The gradient system is split in Z direction.

FIG. 2 shows a prior art configuration for a so-called split mode gradient coil drive using two amplifiers A, B. The typical wiring arrangement is illustrated for the four quadrants of an unrolled transverse gradient coil. Assuming that the patient lies along the Z direction, then amplifier A drives the top or left part of the gradient coil and amplifier B drives the bottom respectively right part of the gradient coil. Utilizing the prior art split amplifier drive in an MRI device does lead to independent sub-coils. However, this particular sub-coil arrangement is not suitably configured to enable reduction of the non-imaging component of the magnetic gradient field. Its merits lie with the control of the absolute value of the magnetic field and the eddy current performance of the gradient system.

FIG. 3 shows the wiring arrangement for the four quadrants Q1, Q2, Q3, Q4 of an unrolled transverse gradient coil that is divided in Z direction into two sub-coils S1, S2, one driven by amplifier A and one driven by amplifier B, but that are electrically connected in a series configuration. Whilst illustrated schematically as four quadrants Q1, Q2, Q3, Q4 of a cylindrical gradient coil, it should be understood that preferably each sub-coil quadrant has also an associated shield or screen coil placed on, and mechanically constrained to, a cylinder with a larger radius. This is illustrated in FIG. 4. The four inner coils I1, I2, I3, I4 are arranged on a cylinder. There are, in addition, four outer coils O1, O2, O3, O4 on a cylinder of larger radius. The current flowing through the inner coils I1, I2, I3, I4 that may be connected in series may flow in the opposite sense in the outer coils O1, O2, O3, O4 depending on the winding direction. Together all eight coils form one axis of a shielded gradient coil. When talking about shielded sub-coils, it is referred to pairs of inner and outer coils as single entities connected to form electrically independent and shielded sub-coils.

FIG. 5 shows the respective wiring arrangement for two sub-coils S1, S2 connected in a parallel configuration. By connecting the sub-coils S1, S2 electrically they can interact in a way to reduce the gradient field component perpendicular to the steady magnetic field of the main magnet system. The series configuration leads to higher maximum current as a function of voltage, thus a larger amplitude of the magnetic gradient field. The parallel configuration leads to a higher voltage as a function of current, thus a shorter rise time of the magnetic gradient field. To allow for individually choosing the imaging modes, i.e. high resolution or low exposure time, the sub-coils are arranged as to permit for switching between different configurations. By using a higher number of sub-coil, configurations mixing parallel and series connections can be chosen to achieve different imaging modes in different imaging regions.

The number of two sub-coils S1, S2 in the examples illustrated in FIGS. 3 and 5 is chosen to illustrate the present invention with respect to a most simple example. The person skilled in the art will understand, that the present invention may be realized with a gradient system divided into more than two sub-coils and more than two gradient amplifiers.

As a further example, FIG. 6 shows the respective wiring arrangement for a gradient system divided not only in Z direction, but also in X or Y direction into four sub-coils driven independently by four amplifiers A1, B1, A2, B2 to reduce the gradient field component perpendicular to the steady magnetic field of the main magnet system for preventing PNS. Each quadrant Q1, Q2, Q3, Q4 corresponds to a sub-coil. This embodiment combines the merit of suppressing PNS with the merits of a split gradient drive as known (see FIG. 2), i.e. control of the absolute value of the magnetic field and suppression of eddy currents.

All embodiments can be improved by using sub-coils that are independently shielded with respect to magnetic field. Independently shielded sub-coils, also known as self shielded sub-coils have a self contained flux return. Self shielded sub-coils show a defined ratio between outer coil current and inner coil current that has to be constant over time for effective shielding. An advantageous property of independently shielded sub-coils is that such structures can be designed to be, during operation, well balanced with respect to certain components of net force and torque such as resulting from Lorenz forces. This is important with respect to minimizing excessive acoustic noise and mechanical vibration.

By modifying the wiring configuration and particularly the split direction as shown for example in FIGS. 3, 5, 6 compared with the wiring arrangement and the split direction shown in FIG. 2, it is possible to control the current in the sub-coils of the gradient system independently. The advantage, with respect to PNS, of this new type of configuration is that the relative current driven to one sub-coils, in particular the relative current driven through the front half of the gradient system with respect to the back half is controlled independently. Thus, the B_{y} (or Bₓ) component can be reduced while still delivering the required imaging gradient field at the iso-center where imaging is done, without the need for e.g. an additional concomitant coil.

As mentioned earlier, in preferred embodiments according to the present invention, this effect is enhanced by one or more sub-coils operating with a current offset in addition to the time dependent current needed for generating the magnetic gradient field. Alternatively, instead of, or in addition to a current offset, each sub-coil can be driven using a different current ratio. A fixed current amplitude plus an additional current offset can be implemented also as a single voltage demand in which a different translation is made between voltage demand level and gradient amplifier, hence current, output.

FIG. 7 illustrates schematically the relative voltage demand on each amplifier per gradient coil half and the resulting magnetic field component when an additional voltage demand offset is supplied. In this case, the constant offset on both sub-coils generates an additional B_{y} field component (solid line). The dotted line shows the equivalent example when the gradient voltage demand is reversed to produce a negative gradient pulse. The voltage demand offset has reverse polarity on one sub-coil relative to the other sub-coil. It is possible as well to have different voltage demand offset on different sub-coils or a voltage demand offset only on one or some sub-coils.

Though the voltage demand offset is shown as a constant, it need only be applied during the imaging gradient pulses. In fact, it can be combined with the imaging gradient pulses since it must also change polarity when the gradient pulses change polarity in order that the field asymmetry does not change with respect to the object to be examined as shown in the B_{y}(z) graph of FIG. 7 by the dotted line.

The additional B_{y} or Bₓ field component leads to a reduced amplitude in the magnetic field of the first sub-coil and inside the measuring space of the MRI device, and thus inside the object to be examined. The higher amplitude induced in the magnetic field of the second sub-coil is harmless as the peak of the amplitude is reached outside the measuring space and thus does not lead to PNS.

In preferred embodiments, the actual voltage demand offset and/or the best sub-coil configuration, with respect to the required image quality, while minimizing the peripheral nerve stimulation to be expected in the object to be examined, may be calculated by the processing unit 12 of FIG. 1 before an exposure. In the not limiting examples illustrated in FIGS. 3, 5 and 6 the configuration of the sub-coils would be a series configuration, a parallel configuration or a configuration where each sub-coil is driven by an own amplifier. The current offset may be implemented as voltage demand offset of the driving amplifier as shown in FIG. 7. Another possibility of setting configuration and/or offset could be to make calibration measurements on populations of patients and then to use the mean best offset and/or configuration. This specific method of operating the MRI device may be implemented as a computer program product that may be stored on a data carrier.

With the knowledge of prior art, it would have been necessary to provide an additional concomitant field coil to generate an additional B_{y} or Bₓ field component. An additional concomitant field coil would lead to a much more complex MRI device, because provisions would have to be taken to shield it, to balance it with respect to net force and torque, to drive it and to integrate it in the overall design of the MRI system. It is a merit of the inventors of the present invention to have developed a gradient system on the basis of standard components like sub-coils and a split drive that provides a magnetic gradient field equivalent to that of a gradient system with an additional concomitant field coil without its negative effects.

While described primarily in the context of a superconducting magnet based cylindrical MRI system, it will be clear to those skilled in the art that the same principles can be extended to superconducting Open MRI or non-superconducting Open or cylindrical MRI systems.

1. A magnetic resonance imaging device, comprising at least:
a main magnet system for generating a steady magnetic field in a measuring space of the magnetic resonance imaging device;
a gradient system with at least one gradient coil for generating a magnetic gradient field in said measuring space;
wherein the magnetic gradient field has at least one component that is perpendicular to the steady magnetic field, wherein the gradient coil is split into sub-coils at least in the direction of the steady magnetic field such that the magnetic gradient field component perpendicular to the steady magnetic field is reduced in a least one region of the measuring space.

2. A magnetic resonance imaging device according to claim 1, wherein each sub-coil is driven by a separate amplifier.

3. A magnetic resonance imaging device according to claim 1, wherein the sub-coils are driven by one or more amplifiers and connected in a parallel configuration.

4. A magnetic resonance imaging device according to claim 1, wherein the sub-coils are driven by one or more amplifiers and connected in a series configuration.

5. A magnetic resonance imaging device according to claim 2 wherein at least one sub-coil operates with a current offset in addition to the time dependent current needed for generating the magnetic gradient field.

6. A magnetic resonance imaging device according to claim 2 wherein the gradient coil is divided into two sub-coils, wherein both sub-coils operate with a current offset in addition to the time dependent current needed for generating the magnetic gradient field, and wherein the one sub-coil operates with the inverse current offset of the other sub-coil.

7. A magnetic resonance imaging device according to claim 3, wherein the sub-coils are arranged to permit for switching between parallel and series configuration.

8. A magnetic resonance imaging device according to claim 5, wherein the device comprises a processing unit to calculate, before taking an image, the best sub-coil configuration and/or the best current offset for the required image quality while minimizing the peripheral nerve stimulation to be expected in the object to be examined.

9. A magnetic resonance imaging device according to claim 1, wherein the sub-coils are independently shielded.

10. A method for operating a magnetic resonance imaging device as claimed in claim 1, comprising the steps of:
calculating the best sub-coil configuration and/or best current offset for the required image quality while minimizing the peripheral nerve stimulation to be expected in the object to be examined before making an exposure;
generating the magnetic gradient field with a reduced magnetic field component perpendicular to the steady magnetic field by using the calculated best sub-coil configuration and/or the calculated best current offset.
